(19) United States
(12) Patent Application Publication
(10) Pub. No.: US 2009/0188106 A1
(43) Pub. Date: Jul. 30, 2009

(54) Delatching of Transceiver Module from Transceiver Module Cage

(75) Inventors: Kenneth Wang, Chengdu (CN); Carl Yang, Chengdu (CN); Mark Wang, Chengdu (CN); Monica Wei, Chengdu (CN); Rang-Chen Yu, San Jose, CA (US)

Correspondence Address: FISH & RICHARDSON, PC, P.O. BOX 1022, MINNEAPOLIS, MN, 55440-1022, US

(73) Assignee: FIBERXON, INC.

(21) Appl. No.: 12/197,981

(22) Filed: Aug. 25, 2008

(30) Foreign Application Priority Data
Aug. 24, 2007 (CN) 200720080793.8

(51) Int. Cl. B23P 19/00; H05K 7/00

(52) U.S. Cl. 29/764; 361/747

(57) ABSTRACT

Designs of a delatching tool for removing pluggable transceiver modules from transceiver module cages and pluggable transceiver module designs having latching mechanisms associated with the delatching tool.

### PRIORITY CLAIM

This application claims the benefit of Chinese Patent Application No. 200720080793.8 filed by Applicant Fiberxon Technology (Chengdu) Co., Ltd. of China on Aug. 24, 2007.

### TECHNICAL FIELD

This specification relates to signal transceiver modules including optical transceiver modules for telecommunications and data communications.

### BACKGROUND

An optical transceiver is an interface device used in optical communication networks to provide conversion between signals in the optical domain and the electronic domain. As such, an optical transceiver includes at least one optical transmitter, e.g., a diode laser, that, in response to an input electrical signal modulated to carry information, produces an output optical signal modulated to carry the information in the input electrical signal, and at least one optical detector that receives and responds to an input optical signal to produce an output electrical signal that carries the information of the input optical signal. Such optical transceivers can be designed to comply with various communication standards in the telecommunication and data communication industries, e.g., data communication data rates at 10 Mbps, 100 Mbps, 1000 Mbps, 10,000 Mbps and higher rates. Optical transceivers can be configured as compact and pluggable optical transceiver modules to fit onto communication line cards and circuit boards. Each optical transceiver module can have an optical interface terminal that receives the input optical signal and the produces the output optical signal and an electrical interface terminal that receives the input electrical signal and outputs the output electrical signal. Optical transceiver modules can be designed under various form factor standards such as the small form-factor pluggable (SFP) optical transceiver modules, 10 Gbps small form factor pluggable (XFP) optical transceiver modules, and SFP+ for the next-generation transceiver module form factor specified by the ANSI T11 Group for 8.5 Gbps and 10 Gbps Fibre Channel and Ethernet applications.

In many pluggable optical transceiver module designs, a pluggable optical transceiver module is inserted into and is fixed on a transceiver module cage via a latching mechanism. The latching mechanism can be designed to include matching latching elements formed on both the transceiver module and the cage. For example, a latch on the cage and a buckle on the transceiver can be used to engage the buckle to the latch to lock the transceiver module in the cage. Various latching mechanism designs for pluggable optical transceiver modules are designed to allow for manual unlocking or delatching of the transceiver module without needing a special delatching tool, where the delatching mechanism is directly formed on the optical transceiver module and is exposed to allow for manual access to release the latch and to simplify operation. Such latching mechanisms can be found in many commercially available small-form pluggable optical transceiver modules (SFP/SFP+), and 10 G optical transceiver module (XFP).

### SUMMARY

This application describes optical and electrical transceiver apparatus, including a delatching tool for removing pluggable transceiver modules from transceiver module cages and pluggable optical transceiver module designs having latching mechanisms associated with the delatching tool. The described examples of pluggable optical transceiver module designs provide latching mechanisms that are designed to delatch from a transceiver module cage by using the accompanying delatching tool and can be difficult to delatch without the accompanying delatching tool. Implementations of the described examples can be used to limit removal of optical transceiver modules in network equipment by an authorized operator with the accompanying delatching tool and thus enhance security and safety associated in use of optical transceivers and facilitate the management of the network equipment.

In one implementation, a delatching tool device for removing a transceiver module plugged in a transceiver module cage out of the transceiver module cage includes a delatching arm comprising an elongated plate body section with a first distal end and a second distal end. The elongated plate body section is structured to fit into two sliding grooves on a top section of the transceiver module to slide between the two sliding grooves. A tool housing is fixed to the delatching arm to allow for a first distal end of the delatching arm to protrude beyond a first side of the tool housing to reach a locking protrusion formed on the top section of the transceiver module when fit into the sliding grooves at a position to remove the locking protrusion from a locking hole in the transceiver module cage. The tool housing includes a shaft fixed to a portion of the tool housing that is spaced from delatching arm and is close to the first distal end of the delatching arm. The delatching tool device also includes a buckle board, a push button and a spring. The buckle board includes an elongated main body with a first distal end and a second distal end, the elongated main body structured to comprise a hole close to the first distal end for engaging to a step formed on a bottom section of the transceiver module opposing the top section. The elongated main body of the buckle board is rotatably engaged to the shaft on the tool housing to pivot around the shaft to extend the first distal end beyond the first side of the tool housing. The push button is connected to the elongated main body of the buckle board at a location close to the second distal end and movably mounted to the tool housing. The spring is engaged to the push button and to one of the tool housing and the delatching arm to exert a force on the buckle board to counter a motion of the push button. Under this design, the push button provides a control mechanism to allow a user to control a position of the first distal end of the buckle board with respect to the first distal end of the delatching arm. In the above delatching tool device, the first distal end of the delatching arm can include a notch for receiving the locking protrusion. The first distal end of the buckle board can include a bent tip pointing away from the delatching arm. The transceiver module can be an electrical transceiver module that receives and transmit electrical signals or an optical transceiver module that receives and transmits optical signals.

In another implementation, a transceiver module that is pluggable in a transceiver module cage includes a transceiver housing elongated to have a first end structured to support an electrical interface terminal and a second end structured to include an input port and an output port, the transceiver housing comprising (1) a top housing cover which includes a locking protrusion for engaging to a mating locking hole of the transceiver module cage, and (2) a fitting engaged at the second end to comprise two symmetric parallel sliding grooves above the top housing cover to receive a delatching arm of a delatching tool for delatching the transceiver housing from the transceiver module cage and a protrusion step on an opposite side of the sliding grooves for engaging to a mating module hole in the delatching tool. The transceiver module also includes a signal transmitter located in the transceiver housing to produce an output signal at the output port; and a signal receiver located in the transceiver housing to receive an input signal received at the input port.

In yet another implementation, a transceiver apparatus includes a transceiver module cage comprising a top cage panel having a locking hole; and a transceiver module having a transceiver housing elongated to have a first end structured to support an electrical interface terminal and a second end structured to support an optical interface terminal that includes an optical input port and an optical output port, the transceiver housing comprising (1) a top housing cover which includes a locking protrusion for engaging to the locking hole of the top cage panel of the transceiver module cage, and (2) a fitting engaged at the second end to comprise two symmetric parallel sliding grooves above the top housing cover to receive a delatching arm of a delatching tool for delatching the transceiver housing from the transceiver module cage and a protrusion step on an opposite side of the sliding grooves for engaging to a mating module hole in the delatching tool.

These and other implementations and examples of techniques and apparatus are described in greater detail in the drawings, the detailed description and the claims.

### BRIEF DESCRIPTION OF DRAWINGS

FIG. 1A illustrates an example of a delatching tool for delatching an optical transceiver module which is not engaged to the delatching tool in one perspective view;

FIG. 1B shows another perspective view of the delatching tool and the optical transceiver module shown in FIG. 1A;

FIG. 2A illustrates the delatching tool and the optical transceiver module in FIGS. 1A and 1B which are engaged to each other;

FIG. 2B shows another perspective view of the delatching tool and the optical transceiver module in FIG. 2A;

FIG. 3A shows one side view of the delatching tool and the optical transceiver module in FIG. 2A;

FIG. 3B shows another side view of the delatching tool and the optical transceiver module in FIG. 2A;

FIG. 4A shows a cross-sectional view of the delatching tool and the optical transceiver module in FIG. 2A;

FIG. 4B shows an enlarged view of partial B in FIG. 4A;

FIG. 4C shows an enlarged view of partial A in FIG. 4A;

FIGS. 5A and 5B show two perspective views of an example of a transceiver module cage and the optical transceiver module shown in FIGS. 1A and 1B in an engaged configuration.

FIGS. 5C and 5D show two perspective views of the transceiver module cage and the optical transceiver module shown in FIGS. 5A and 5B in an unengaged configuration.

FIG. 6 shows a process for using the delatching tool in FIGS. 1A, 1B and 4A-4C in removing the optical transceiver module in FIGS. 1A and 1B from a cage.

### DETAILED DESCRIPTION

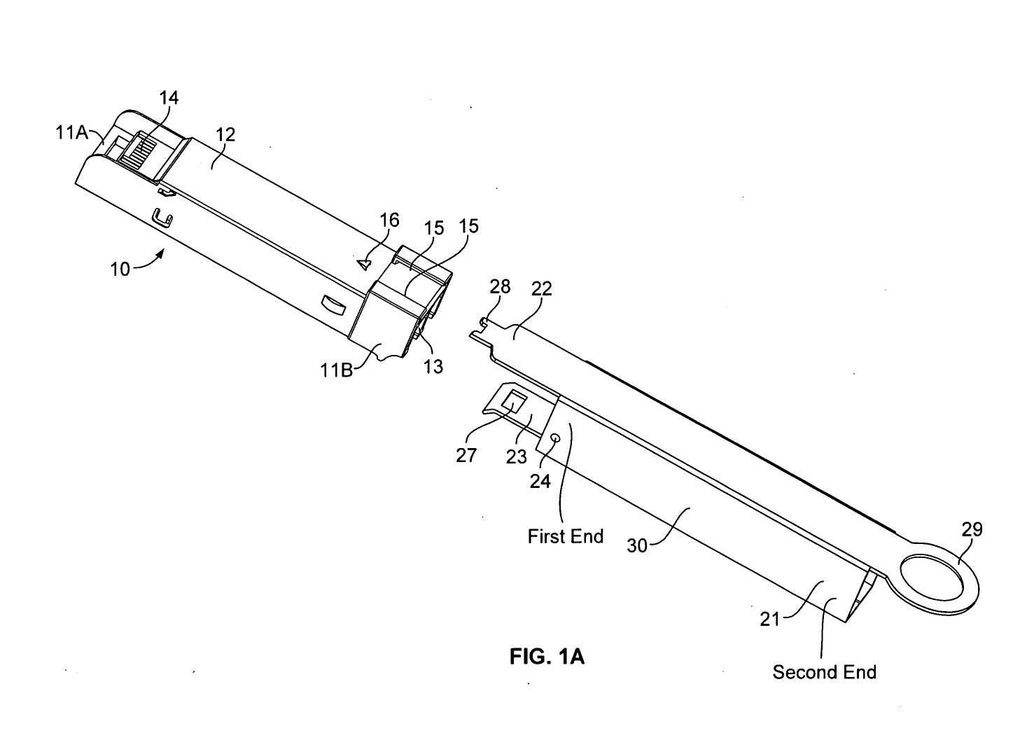

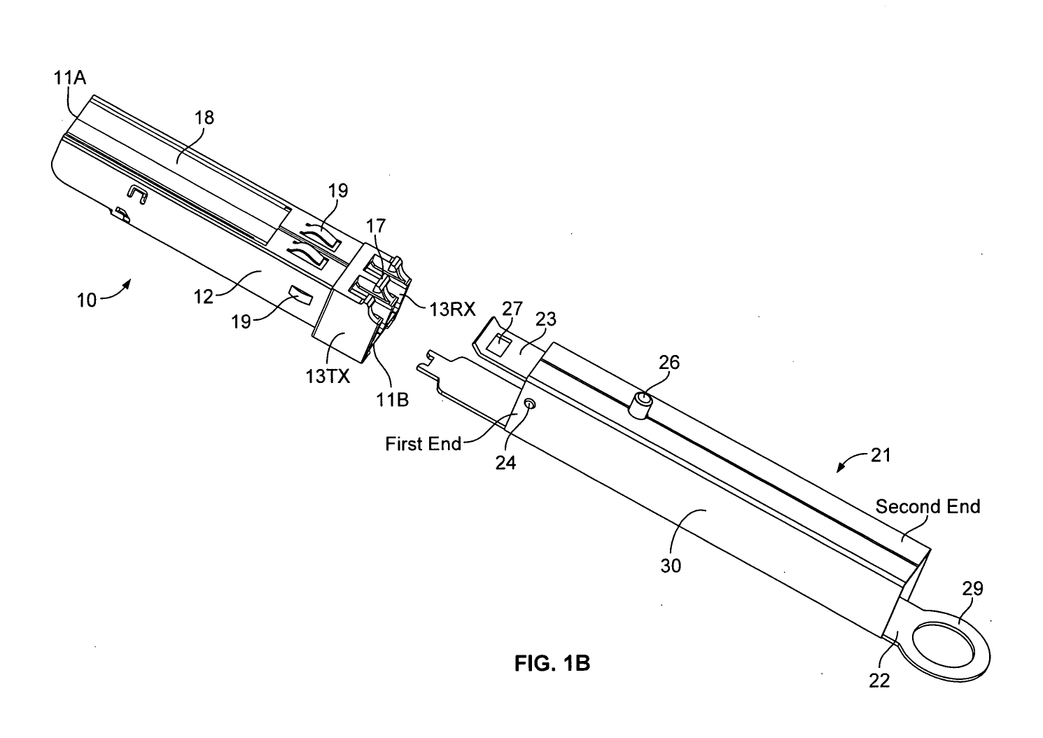

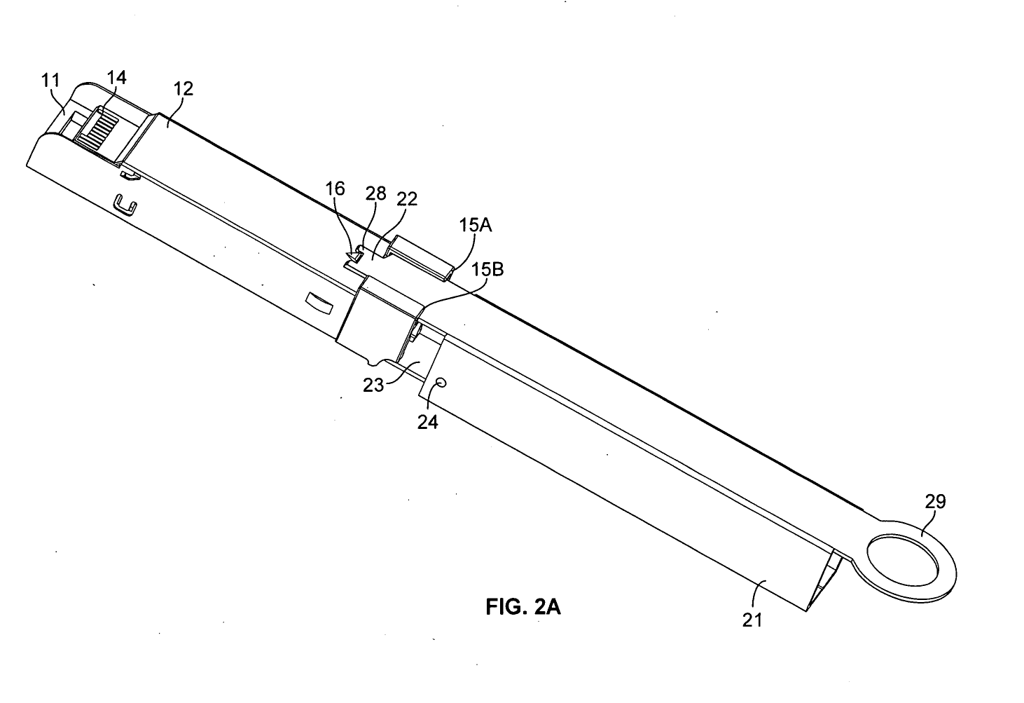

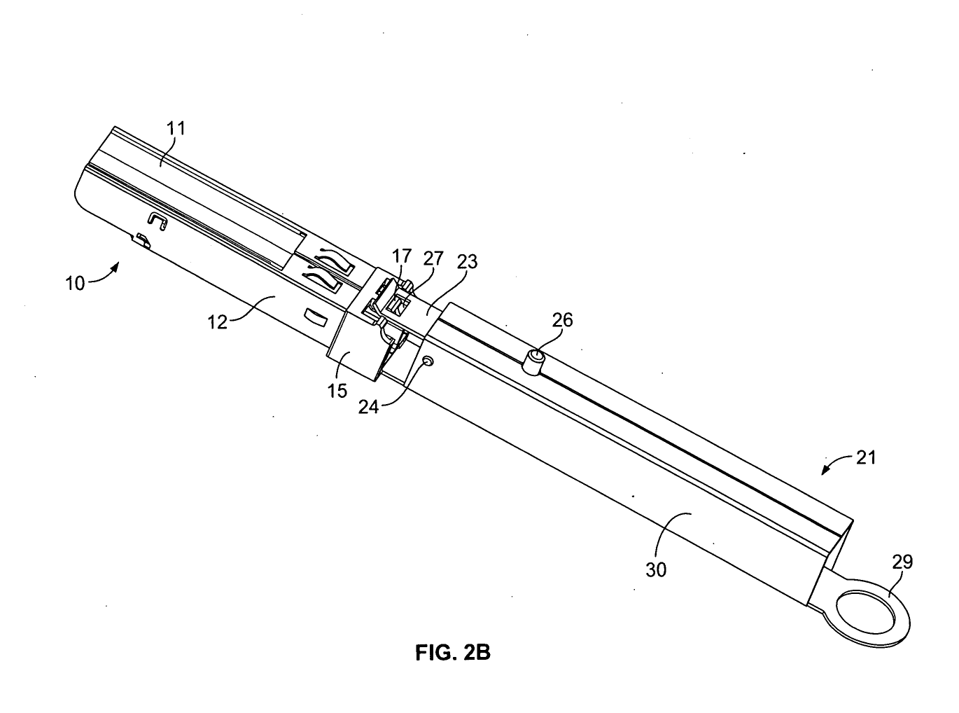

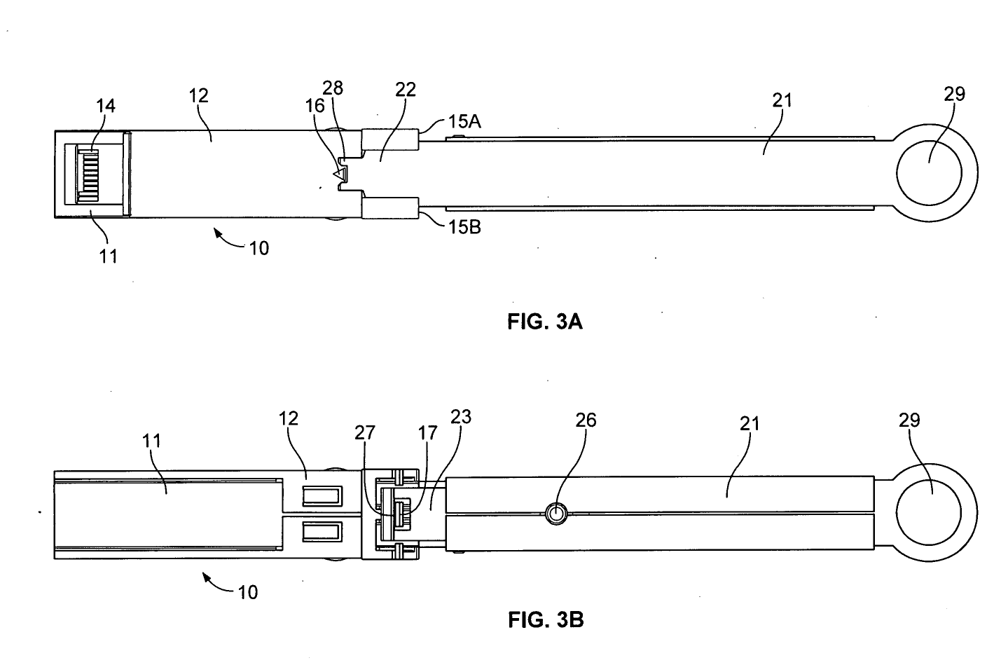

FIGS. 1A and 1B, 3A, 3B and 4A-C illustrates various features of an example of an optical transceiver module 10 for a suitable small form factor standard such as the SFP, SFP+ and XFP. The transceiver module 10 includes a housing 11 generally elongated to have a first end 11A as an electrical interface terminal and a second opposite end 11B as an optical interface 13. The housing 11 includes elongated sidewalls and a top housing cover 12 engaged to one another to form a chamber in which an optical transmitter, an optical receiver, electronic circuitry and other components are mounted. On the opposite side of the housing cover 12 is a bottom 18 of the housing 11. The housing cover 12 may be shorter than the sidewalls to expose a portion of the first end 11A of the housing 11 so that the electrical interface terminal of the electronic circuitry of the optical transceiver module 10 can be connected to a circuit board of a communication device such as a router or a switch. The housing 11 may be made of a metal and include electrical grounding fingers 19. FIG. 1A shows a connector interface 14 of the electrical interface terminal in the exposed portion at the first end 11A of the housing 11. The optical interface 13 at the second end 11B of the housing 11 includes an optical output port 13TX and an optical receiver port 13RX. Each of the optical ports 13TX and 13RX is designed to receive and engage with an optical cable to receive or output an optical signal via the optical cable. The output optical signal from the optical transmitter in the optical transceiver module 10 is output at the optical port 13TX. An input optical signal from a fiber cable is directed into the optical receiver in the optical transceiver module 10 via the optical port 13RX. The cross sectional shape of the two ends 11A and 11B is rectangular in the example shown and can be square, rectangular or other suitable shapes.

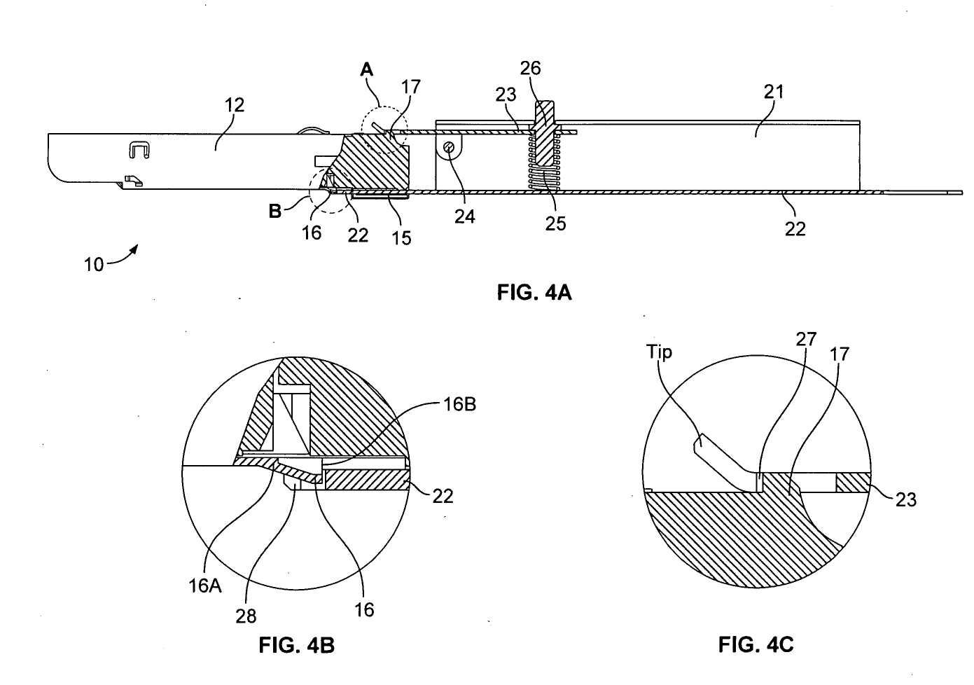

The top housing cover 12 includes a locking protrusion in form of a trigon bulge 16 for engaging to a mating locking hole of a transceiver module cage. Referring to FIGS. 4A and 4B, the locking trigon bulge 16 has a sloped bulging profile 16A facing the first end 11A of the housing 11 and a substantially vertical facet 16B facing the second end 11B of the housing 11. The locking trigon bulge 16 can fit into the mating locking hole of the transceiver module cage to lock the position of the optical transceiver module 10 in the transceiver module cage. In addition, a delatching tool 21 can be engaged to the locking trigon bulge 16 to remove the locking trigon bulge 16 out of the mating locking hole of the transceiver module cage when using the tool 21 to remove the optical transceiver module 10 out of the transceiver module cage. The first end 11A of the housing 11 is inserted into an opening of the transceiver module cage until the locking trigon bulge 16 fits into the mating locking hole of the transceiver module cage. The delatching tool 21 is used to engage the plugged optical transceiver module 10 and to delatch the housing 11 from the cage by pulling the optical transceiver module 10 out of the cage. In this context, the optical transceiver module 10 is a pluggable module in terms of engaging to the transceiver module cage.

The second end 11B of the housing 11 is engaged to a fitting 15 that includes two symmetric parallel sliding grooves 15A and 15B on the top housing cover 12 to receive a delatching arm 22 from the tool 21. The height of the grooves 15A and 15B is not greater than the height of the locking trigon bulge 16 so that an end facet of the delatching arm 22 can be guided to the locking trigon bulge 16 to contact the end facet 16B. The opposite, bottom side of the fitting 15 is structured to include a protrusion step 17 that protrudes above the bottom side surface 18 of the housing 11. This protrusion step 17 is used to engage to a mating module hole 27 in the delatching tool 21 when used to unplug the optical transceiver module 10 from the cage and to remove the optical transceiver module 10 out of the cage.

The detaching tool 21 is specially designed to operate with the optical transceiver module 10. The detaching tool 21 includes a delatching arm 22 and a buckle board 23 that are arranged to oppose and to be parallel to each other with a spacing of about the distance between the bottom side surface 18 and the top housing cover 12 of the optical transceiver module 10 (FIG. 4A). A tool housing 30 is provided and is fixed to the delatching arm 22 to allow for a first end of the delatching arm 22 to protrude beyond the housing 30. The tool housing 30 can operate as a handle for the operator to hold and operate the delatching tool 21, in addition to other functions. The delatching arm 22 includes at least a portion that is close to the first end to have a width to be slightly less than the spacing between the two parallel sliding grooves 15A and 15B on the fitting 15 of the optical transceiver module 10 so that this portion of the delatching arm 22 can fit into the two sliding grooves 15A and 15B and can be guided by the two sliding grooves 15A and 15B along the longitudinal direction of the optical transceiver module 10. The first end of the delatching arm 22 includes a distal end 28 for contacting the locking trigon bulge 16 on the optical transceiver module 10 when removing the locking trigon bulge 16 out of the locking hole in the cage. As illustrated, the distal end 28 can be smaller in dimension than the rest of the delatching arm 22 and may have a “U” shape to have an opening at the end facet that is slightly larger than the dimension of the locking trigon bulge 16 for easy engagement with the locking trigon bulge 16. The second opposing end of the delatching arm 22 can be structured to include a ring hole or a pothook ring 29 for being conveniently carried around by a user.

The buckle board 23 is rotatably engaged to the assembly of the tool housing 30 and the delatching arm 22. Referring to FIG. 4A, the tool housing 30 includes a fixed shaft 24 engaged to the tool housing 30 near the first end. The fixed shaft 24 is along a direction that is perpendicular to the elongated direction of the delatching arm 22. The buckle board 23 is rotatably engaged to the shaft 24 to have the desired spacing. The first distal end of the buckle board 23 extends and protrudes beyond the tool housing 30 on the same side of the distal end 28 of the delatching arm 22 and is structured to include the module hole 27 for engaging to the step 17 on the optical transceiver module 10. Referring to FIG. 4C, the distal tip of the buckle board 23 may be a curved bending section that points away from the delatching arm 22 to allow for easy engagement with the fitting 15 to allow for the step 17 to smoothly enter the module hole 27 on the buckle board 23 in a plug-in action when the detaching tool 21 is directed to engage to the optical transceiver module 10. The second distal end of the buckle board 23 is engaged to a push button 26 which is movably mounted to the tool housing 30 and is connected to a spring 25 so that the buckle board 23 effectuates a lever with respect to the pivot point engaged to the shaft 24. The push button 26 is to act on the second distal end (rear part) of the buckle board 23 in the reverse direction of the action from the spring 25. The push button 26 and the spring 25 are structured in a way that the spring 25 is loaded to place the buckle board 23 to be approximately parallel to the delatching arm 22 when the push button 26 is not pushed. At this default position, the delatching tool 21 is directed by the user to engage to the fitting 15 of the optical transceiver module 10 plugged in the transceiver module cage by sliding the delatching arm 22 in the sliding grooves 15A and 15B to contact the distal facet 28 to the locking trigon bulge 16 on the top side of the optical transceiver module 10 (FIG. 4B) and engaging the protrusion step 17 on the bottom side of the fitting 15 into the module hole 27 of the buckle board 23 (FIG. 4C). Pushing the push button 26 causes the first distal end of the buckle board 23 to move away from the delatching arm 22 and to release the step 17 from the module hole 27.

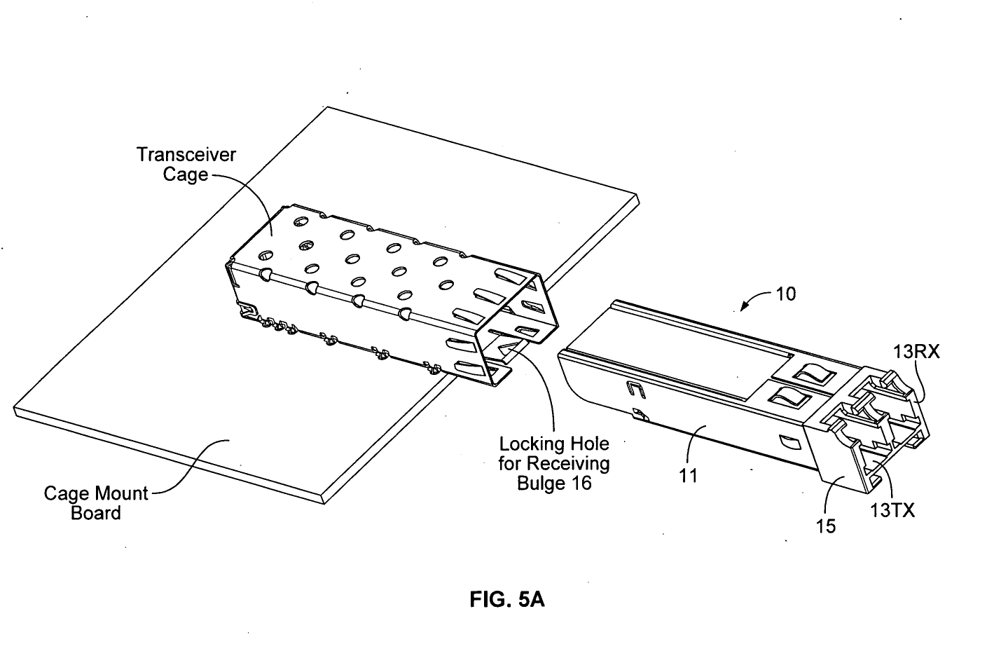

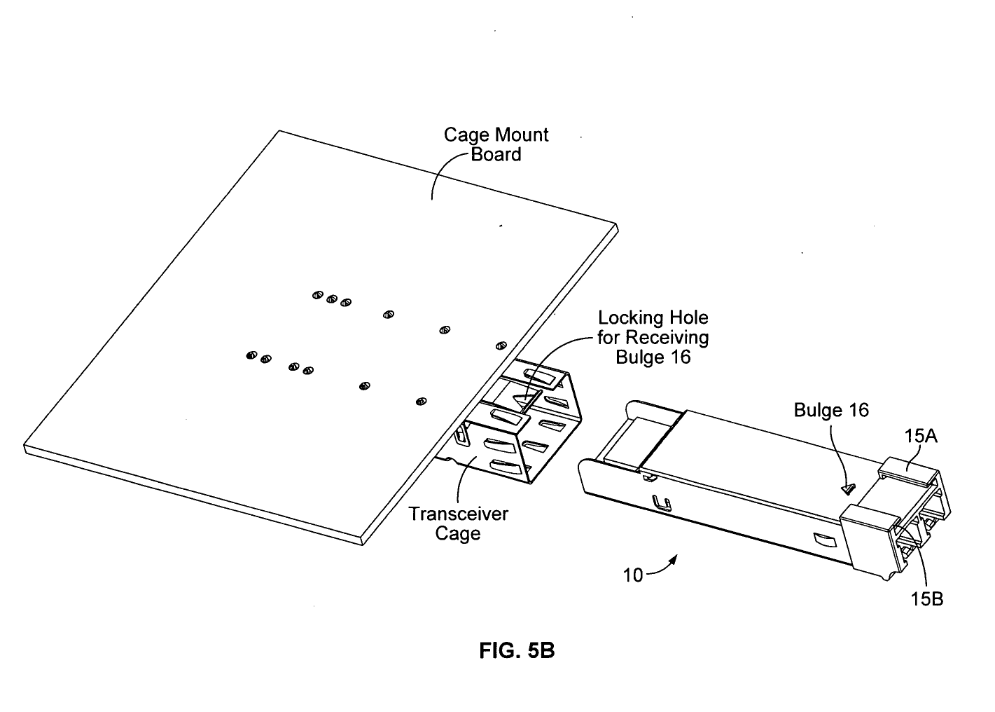

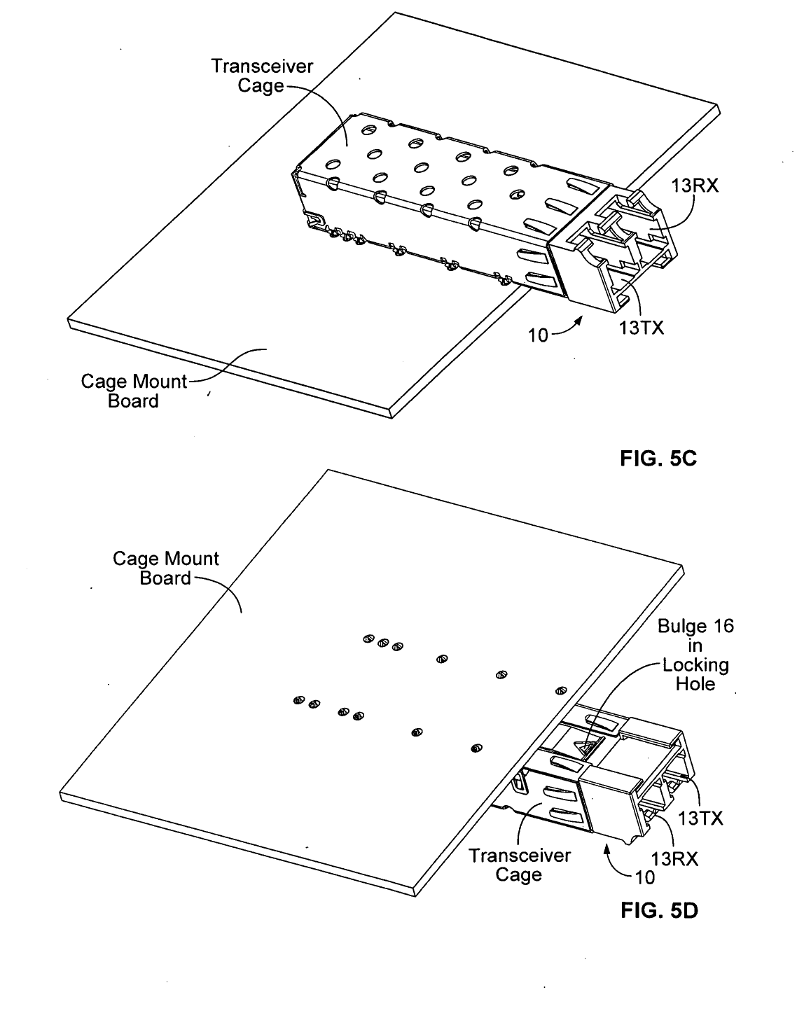

FIGS. 5A, 5B, 5C and 5D show an example of a transceiver module cage and the optical transceiver module shown in FIGS. 1A and 1B in both unengaged and engaged configurations. The optical transceiver module 10 can be easily plugged to the transceiver module cage by first pushing the housing 11 to slide into the cage and by plugging the electric interface 14 into an electrical receptacle in the cage until the trigon bulge 16 slides into the locking hole on the top plane of the cage. This locks the optical transceiver module 10 in the cage. Next, a fiber jumper is inserted into an optical port 13TX or 13RX of the optical interface 13.

In the above example, a delatching key is not provided to allow a user to conveniently delatch the locking trigon bulge 16 and the locking hole in the upper inner surface of the cage. This lack of the delatching key is intentional and is part of the design. In absence of such a delatching key, when the optical transceiver module 10 is plugged into the transceiver module cage by locking the locking trigon bulge 16 into the locking hole in the upper inner surface of the cage, the latching mechanism is either not easily accessible or is concealed from the user. The user cannot readily access the locking trigon bulge 16 to delatch the engagement between the locking trigon bulge 16 and the locking hole in the upper inner surface of the cage. Hence, this design makes it difficult for a user, without the delatching tool 21, to manually delatch the plugged optical transceiver module 10 in the cage. In this regard, this design is different from various optical transceiver module designs which provide a user accessible delatching key to allow a person, without using any special tooling, to manually delatch the plugged optical transceiver module from the cage and thus to remove the optical transceiver module. The delatching tool 21 in the above example is provided as a substitute for the conventional delatching key and is used to effectuate the function of the delatching key in various other optical transceiver module designs for delatching the plugged optical transceiver module 10 in the cage. This delatching tool is designed to be a separate piece from the optical transceiver module 10 and the transceiver module cage. As such, without the delatching tool 21, the plugged optical transceiver module 10 in the cage cannot be easily delatched and removed from the cage. Therefore, this use of the delatching tool 21 allows the access to the optical transceiver modules to be controlled by controlling the delatching tool 21 and can be used to provide facilitate management of security and safety of the optical transceiver modules.

Suitable materials can be used to construct various parts of the delatching tool 21. For example, a stainless steel material can be used to for parts of the delatching tool 21. The optical transceiver module 10 may use a pressed Zinc alloy material and a plate metal material to reliably shield the inner circuit as well as to tightly contact with the inner heating optical transceiver component to fully disperse the heat.

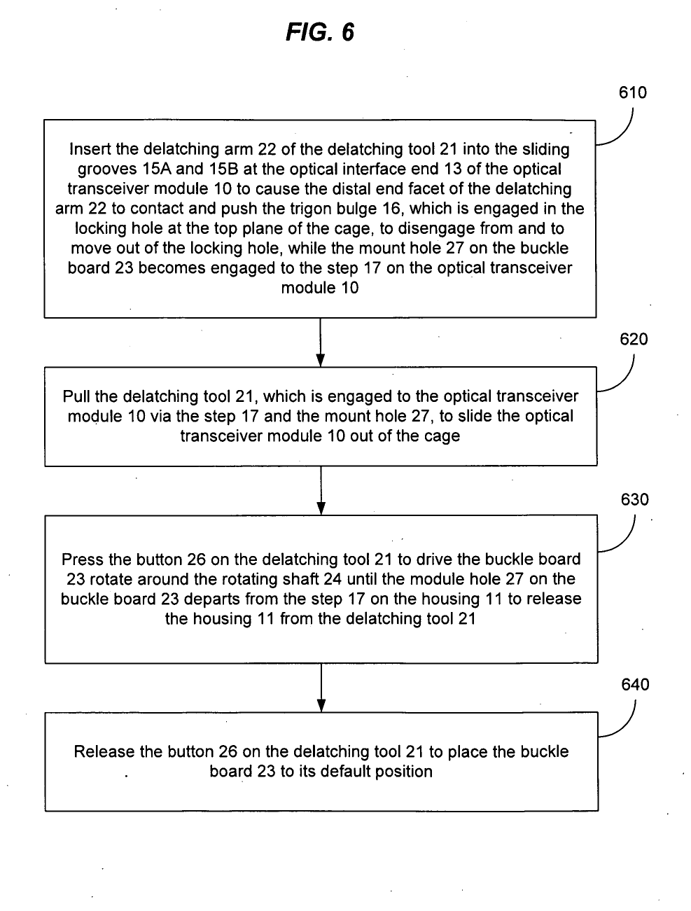

FIG. 6 shows an example of process for using the delatching tool in FIGS. 1A, 1B and 4A-4C in unplugging and removing the optical transceiver module 10 in FIGS. 1A and 1B from a cage. When the optical transceiver module 10 is plugged inside the cage, the trigon bulge 16 sits inside the locking hole at the top plane of the cage and thus locks the optical transceiver module 10 to the cage. To remove the optical transceiver module 10, the delatching arm 22 of the delatching tool 21 is aimed at the sliding grooves 15A and 15B at the optical interface end and is inserted to slide along the sliding grooves 15A and 15B until the “U”-shape delatching fork 28 at the front part of the delatching arm 22 contacts the trigon bulge 16 while the mount hole 27 on the buckle board 23 becomes engaged to the step 17 on the optical transceiver module 10. At this position, the delatching tool 21 can be further pushed to cause the trigon bulge 16 to disengage from and draw back out of the locking hole at the top plane of the cage so that the optical transceiver module 10 is no longer locked to the cage. This completes the delatching of the housing 11 from the cage (610). At this time, the module hole 27 of the buckle board 23 on the delatching tool 21 clasps with the step 17 on the housing 11 so that housing 11 is engaged to the buckle board 23. Next, the delatching tool 21 is pulled to drag the optical transceiver module 10 out of the cage by the operator (620). After the optical transceiver module 10 is out of the cage, the push button 26 on the delatching tool 21 is pressed to drive the buckle board 23 rotate around the shaft 24 until the module hole 27 on the buckle board 23 departs from the step 17 on the housing 11. This releases the optical transceiver module 10 from the delatching tool 21. The push button 26 can be released to allow the spring 25 to push the push button 26 and the buckle board 23 to their default positions.

The above designs for the optical transceiver module and the delatching tool may also be adapted for designing an electrical transceiver module and an associated delatching tool. For example, an electrical transceiver module can be similarly constructed as the optical transceiver module 10 where the ports 13TX and 13RX are an electrical output port and an electrical input port, respectively. The port 13TX can be used to receive and engage to an electrical cable that receives the electrical output signal output by the transceiver module. The port 13RX can be used to receive and engage to an electrical cable that carries the electrical input signal to be received by the transceiver module. The corresponding delatching tool can be similarly constructed as the delatching tool 21 described above.

While this specification contains many specifics, these should not be construed as limitations on the scope of an invention that is claimed or of what may be claimed, but rather as descriptions of features specific to particular embodiments. Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or a variation of a sub-combination. Similarly, while operations are depicted in the drawings in a particular order, this should not be understood as requiring that such operations be performed in the particular order shown or in sequential order, or that all illustrated operations be performed, to achieve desirable results.

Only a few examples and implementations are disclosed. Variations, modifications and enhancements to the described examples and implementations and other implementations may be made based on what is disclosed.

What is claimed is:

1. A delatching tool device for removing a transceiver module plugged in a transceiver module cage out of the transceiver module cage, comprising:
a delatching arm comprising an elongated plate body section with a first distal end and a second distal end, the elongated plate body section structured to fit into two sliding grooves on a top section of the transceiver module to slide between the two sliding grooves;
a tool housing fixed to the delatching arm to allow for a first distal end of the delatching arm to protrude beyond a first side of the tool housing to reach a locking protrusion formed on the top section of the transceiver module when fit into the sliding grooves at a position to remove the locking protrusion from a locking hole in the transceiver module cage, the tool housing comprising a shaft fixed to a portion of the tool housing that is spaced from delatching arm and is close to the first distal end of the delatching arm;
a buckle board comprising an elongated main body with a first distal end and a second distal end, the elongated main body structured to comprise a hole close to the first distal end for engaging to a step formed on a bottom section of the transceiver module opposing the top section, the elongated main body being rotatably engaged to the shaft on the tool housing to pivot around the shaft to extend the first distal end beyond the first side of the tool housing;
a push button connected to the elongated main body of the buckle board at a location close to the second distal end and movably mounted to the tool housing; and
a spring engaged to the push button and to one of the tool housing and the delatching arm to exert a force on the buckle board to counter a motion of the push button,
wherein the push button provides a control mechanism to allow a user to control a position of the first distal end of the buckle board with respect to the first distal end of the delatching arm.

2. The device as in claim 1, wherein the first distal end of the delatching arm has a notch for receiving the locking protrusion.

3. The device as in claim 1, wherein the first distal end of the buckle board includes a bent tip pointing away from the delatching arm.

4. A transceiver module that is pluggable in a transceiver module cage, comprising:
a transceiver housing elongated to have a first end structured to support an electrical interface terminal and a second end structured to include an input port and an output port, the transceiver housing comprising (1) a top housing cover which includes a locking protrusion for engaging to a mating locking hole of the transceiver module cage, and (2) a fitting engaged at the second end to comprise two symmetric parallel sliding grooves above the top housing cover to receive a delatching arm of a delatching tool for delatching the transceiver housing from the transceiver module cage and a protrusion step on an opposite side of the sliding grooves for engaging to a mating module hole in the delatching tool;
a signal transmitter located in the transceiver housing to produce an output signal at the output port; and
a signal receiver located in the transceiver housing to receive an input signal received at the input port.

5. The transceiver module as in claim 4, where in the locking protrusion has a sloped bulging profile facing the first end and a substantially vertical facet facing the second end.

6. The transceiver module as in claim 4, wherein each of the input port and the output port is structured to engage an optical fiber cable, wherein the signal transmitter is an optical transmitter, and wherein the signal receiver is an optical receiver.

7. The transceiver module as in claim 4, wherein each of the input port and the output port is structured to engage an electrical cable, wherein the signal transmitter is an electrical signal transmitter, and wherein the signal receiver is an electrical signal receiver.

8. A transceiver apparatus, comprising:
a transceiver module cage comprising a top cage panel having a locking hole; and
a transceiver module having a transceiver housing elongated to have a first end structured to support an electrical interface terminal and a second end structured to support an optical interface terminal that includes an optical input port and an optical output port, the transceiver housing comprising (1) a top housing cover which includes a locking protrusion for engaging to the locking hole of the top cage panel of the transceiver module cage, and (2) a fitting engaged at the second end to comprise two symmetric parallel sliding grooves above the top housing cover to receive a delatching arm of a delatching tool for delatching the transceiver housing from the transceiver module cage and a protrusion step on an opposite side of the sliding grooves for engaging to a mating module hole in the delatching tool.

9. The transceiver apparatus as in claim 8, wherein the transceiver module comprises an optical transmitter located in the transceiver housing to produce output light at the optical output port; and an optical receiver located in the transceiver housing to receive input light received at the optical input port.

10. The transceiver apparatus as in claim 8, where in the locking protrusion has a sloped bulging profile facing the first end and a substantially vertical facet facing the second end.

11. The transceiver apparatus as in claim 8, wherein each of the optical input port and the optical output port is structured to engage an optical fiber cable.
